(19) United States
(12) Patent Application Publication
(10) Pub. No.: US 2025/0271767 A1
(43) Pub. Date: Aug. 28, 2025

(54) THINNER COMPOSITION FOR REMOVING PHOTOSENSITIVE RESIN AND ANTI-REFLECTIVE COATING, AND METHOD FOR REMOVING PHOTOSENSITIVE RESIN AND ANTI-REFLECTIVE COATING USING THE SAME

(71) Applicant: DONGWOO FINE-CHEM CO., LTD., Iksan-si (KR)

(72) Inventors: Tae-Kyung LEE, Iksan-si (KR); So-Min LEE, Iksan-si (KR); Ji-Min CHUN, Iksan-si (KR)

(73) Assignee: DONGWOO FINE-CHEM CO., LTD., Iksan-si (KR)

(21) Appl. No.: 19/057,959

(22) Filed: Feb. 19, 2025

(30) Foreign Application Priority Data
Feb. 26, 2024 (KR) 10-2024-0027051

(51) Int. Cl. G03F 7/42; C09D 9/00

(52) U.S. Cl. CPC G03F 7/422; C09D 9/005

(57) ABSTRACT

The present disclosure provides a thinner composition including a cyclic ketone-based compound and a cyclic hydrocarbon compound, and a method for removing a photosensitive resin and an anti-reflective coating using the same.

### CROSS-REFERENCE TO RELATED APPLICATION(S)

This application claims the benefit under 35 USC 119 (a) of Korean Patent Application No. KR 10-2024-0027051, filed on Feb. 26, 2024, with the Korean Intellectual Property Office, the disclosure of which is incorporated herein by reference in its entirety.

### TECHNICAL FIELD

The present disclosure relates to a thinner composition for removing a photosensitive resin and an anti-reflective coating used in processes for manufacturing a semiconductor device and a thin film transistor liquid crystal display device, and a method for removing a photosensitive resin and an anti-reflective coating using the same.

### BACKGROUND ART

Among semiconductor device manufacturing processes, a photo lithography process is a process in which a photosensitive resin composition is applied on a wafer, a pre-designed pattern is transferred, and then an electronic circuit is formed through an appropriate etching process along the transferred pattern, and is one of very important processes.

Such a photo lithography process is performed by (1) an application process of uniformly applying a photosensitive resin composition on a surface of a wafer, (2) a soft baking process of evaporating a solvent from the applied photosensitive film so that the photosensitive film is attached to the surface of the wafer, (3) an exposure process of, while repeatedly and sequentially reducing and projecting a circuit pattern on a mask using a light source such as ultraviolet light, exposing the photosensitive film to transfer the pattern of the mask on the photosensitive film, (4) a development process of selectively removing portions that have different physical properties such as a difference in solubility resulting from photosensitization by the exposure to a light source using a developing solution, (5) a hard baking process for more closely fixing the photosensitive film, which remains on the wafer after the development process, on the wafer, (6) an etching process of etching a certain portion along the pattern of the developed photosensitive film and (7) a peeling process of removing the unnecessary photosensitive film after the above-described processes.

Among the photo lithography processes, the rotational application process of supplying a photosensitive film on a wafer and rotating the substrate to evenly spread the surface by centrifugal force causes the photosensitive film to be driven to the edge portion and the rear surface of the substrate due to the centrifugal force, forming small spherical substances. The spherical substances are peeled off during the substrate transfer after going through the bake process, causing particles in the device, and also causing defocus during the exposure. Such unnecessary photosensitive materials cause equipment contamination and reduce the yield in a semiconductor device manufacturing process, and therefore, in order to remove the unnecessary photosensitive materials, spray nozzles are installed above and below edge and rear surface portions of a substrate, and a thinner composition formed with organic solvent components is sprayed onto the edge and rear surface portions through the nozzles to remove them.

Factors determining performance of the thinner composition include a dissolution rate, volatility and the like. A dissolution rate of a thinner composition is very important as an ability of determining how effectively and quickly it is able to dissolve and remove a photosensitive resin. Specifically, in rinsing an edge portion, an appropriate dissolution rate is required to have a smooth processing section, and when the dissolution rate is too high, a photosensitive film attack may occur in rinsing the photosensitive film applied on a substrate. On the contrary, when the dissolution rate is too low, a partially dissolved photosensitive film tail flow phenomenon, which is called tailing, may occur in rinsing the photosensitive film applied on a substrate. Particularly, in a rinse process using a rotary applicator, reducing the rotation speed to low rotation (rpm) is inevitable due to diameter enlargement in a substrate resulting from recent high integration and high density of semiconductor integrated circuits.

Korean Patent Application Laid-Open No. 10-2005-0080603 discloses a composition including propylene glycol monomethyl ether acetate (PGMEA), ethyl lactate (EL), methyl 2-hydroxy-2-methyl propionate (HBM) and the like. However, existing thinner compositions such as the thinner composition include a composition with high polarity in order to improve solubility and EBR (Edge Bead Removal) properties for photoresists with high polarity, and when the polarity is too high, the speed at which the photoresist is swollen from the end of the EBR toward the center of the wafer increases, which causes a problem of increasing a Hump height and reducing film uniformity. In addition, the high Hump height reduces an available area and increases defects generated by the Hump in the subsequent processes, causing a problem of reducing the yield, and a solution for these problems has been required.

### PRIOR ART DOCUMENTS

### Patent Documents

(Patent Document 1] Korean Patent Application Laid-Open No. 10-2005

### Disclosure

### Technical Problem

The present disclosure has been made in view of the above, and is directed to providing a thinner composition having uniform removal capability for an unnecessary photosensitive film generated on an edge or rear surface portion of a substrate caused by diameter enlargement in the substrate used for manufacturing a semiconductor device and a thin film transistor liquid crystal display device.

In particular, the present disclosure is directed to providing a thinner composition capable of lowering a Hump height while having excellent solubility and EBR properties for photoresists and anti-reflective coatings for KrF, ArF and EUV.

### Technical Solution

One embodiment of the present disclosure provides a thinner composition including a cyclic ketone-based compound and a cyclic hydrocarbon compound, and a method for removing a photosensitive resin and an anti-reflective coating using the same. One embodiment of the present disclosure includes a method for removing a photosensitive resin, the method including removing a photosensitive resin on a substrate using the thinner composition.

One embodiment of the present disclosure includes a method for removing an anti-reflective coating, the method including removing an anti-reflective coating on a substrate using the thinner composition.

### Advantageous Effects

A thinner composition according to the present disclosure is used on edge and rear surface portions of a substrate used in a method for manufacturing a semiconductor device and a thin film transistor liquid crystal display device, and provides an effect of efficiently removing an unnecessarily attached photosensitive film in a short period of time.

In particular, the present disclosure provides a thinner composition capable of lowering a Hump height while having excellent solubility and EBR properties for photoresists and anti-reflective coatings for KrF, ArF and EUV (extreme ultraviolet).

In addition, by controlling polarity of the thinner composition, the speed at which the photoresist is swollen by a thinner from the end of the EBR toward the center of the wafer is reduced, lowering the Hump height, and as a result, the available area increases and defects generated by the Hump in subsequent processes are reduced, improving a yield.

### BEST MODE

One embodiment of the present disclosure provides a thinner composition including a cyclic ketone-based compound and a cyclic hydrocarbon compound, and a method for removing a photosensitive resin and an anti-reflective coating using the same.

The thinner composition according to the present disclosure may be preferably used for removing a photosensitive resin and/or an anti-reflective coating used in processes for manufacturing a semiconductor device and a thin film transistor liquid crystal display device. The photosensitive resin may be one or more types of photoresists for ArF, KrF and EUV.

By the thinner composition according to the present disclosure including both a cyclic ketone-based compound and a cyclic hydrocarbon compound, a Hump height may be lowered while having excellent solubility and EBR properties for photosensitive resins and/or anti-reflective coatings including a photoresist (PR) for KrF, ArF and EUV. In addition, by controlling polarity of the thinner composition, the speed at which the photoresist (PR) is swollen by a thinner from the end of the EBR toward the center of the wafer is reduced, lowering the Hump height, and as a result, the available area increases and defects caused by the Hump in subsequent processes are reduced, improving a yield.

Specifically, when removing an unnecessary portion in the photosensitive resin and/or the anti-reflective coating formed on the substrate (wafer), an edge portion of the photosensitive resin and/or the anti-reflective coating is swollen, forming a step higher than portions of the photosensitive resin and/or the anti-reflective coating other than the edge portion. This is referred to as a “Hump”, and the step is referred to as a “Hump height”.

In addition, the thinner composition of the present disclosure has high work stability since it is non-toxic to the human body and has no unpleasantness caused by the order, and does not generate an attack for a substrate to be cleaned since it has low corrosiveness.

### <Thinner Composition>

The thinner composition of the present disclosure includes a cyclic ketone-based compound and a cyclic hydrocarbon compound, and is thereby effective in simultaneously improving solubility of polar and nonpolar photoresists. The cyclic ketone-based compound improves solubility of a photoresist with high polarity, and the cyclic hydrocarbon compound improves solubility of a photoresist with low polarity. In addition, the thinner composition of the present disclosure may further include an organic solvent.

### (a) Cyclic Ketone-Based Compound

In the present disclosure, the cyclic ketone-based compound has a cyclic structure and thus has good affinity with similar cyclic resins. Furthermore, the cyclic ketone-based compound of the present disclosure has high polarity and thus exhibits high solubility or dissolution rate for most photoresists and hard masks. In addition, the cyclic ketone-based compound has a property of high volatility, and therefore, may reduce a phenomenon of the end of dissolved PR flowing down in the drying process of an EBR process.

More specifically, the cyclic ketone-based compound of the present disclosure may include one or more types of compounds selected from the following Chemical Formulae 1-1 to 1-3.

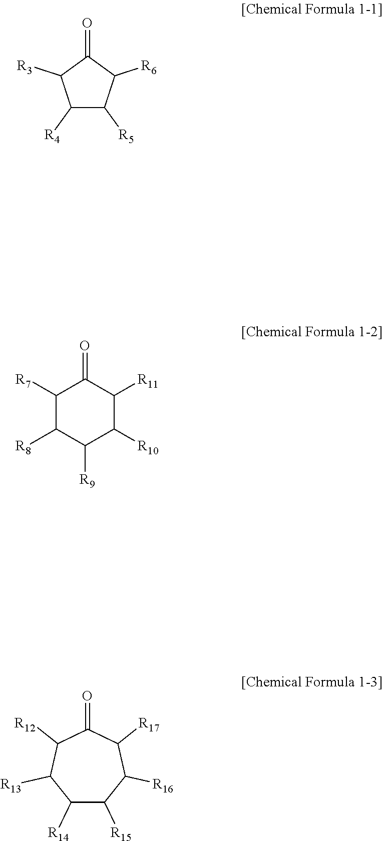

In Chemical Formulae 1-1 to 1-3,
R₃ to R₁₇, each independently, represent a hydrogen atom, an alkyl group having 1 to 5 carbon atoms, a hydroxyl group, an alkyl ether group, a thiol group, an amine group, a carboxyl group, a ketone group, an alkyl ketone group or an alkyl ester group.

In addition, the cyclic ketone-based compound may include one or more types selected from among cyclopentanone, cyclohexanone, cycloheptanone, 1,3-cyclopentanedione, 3-hydroxycyclopentanone and 3-oxocyclopentanecarboxylic acid.

The cyclic ketone-based compound included in the thinner composition of the present disclosure is preferably included in an amount of 0.1% by weight to 99.9% by weight and more preferably included in an amount of 1% by weight to 50% by weight with respect to the total weight of the composition. When the above-described range is satisfied, performance may be more preferably improved when organic solvents other than the cyclic ketone-based compound are mixed, and particularly, RRC (reducing resist coating) performance may be greatly improved in the evaluation when solvents with low volatility are mixed. When the corresponding content range is satisfied, results of excellent EBR image and minimized Hump height may be obtained in the photoresist coating. However, when the content is outside the above-mentioned content range, it is difficult to expect straightness of the EBR image, or the Hump height is likely to increase.

### (b) Cyclic Hydrocarbon Compound

The cyclic hydrocarbon compound has a cyclic structure similar to a cyclic ketone, thereby having good affinity with similar cyclic resins, and has low polarity since no functional group is present compared to a cyclic ketone having high polarity. Accordingly, the cyclic hydrocarbon compound has advantages of achieving excellent EBR image, minimizing Hump height and further improving film uniformity when coating various types of photoresists including even highly hydrophobic resins.

The cyclic hydrocarbon compound may include one or more types of compounds selected from the following Chemical Formula 2-1 and Chemical Formula 2-2.

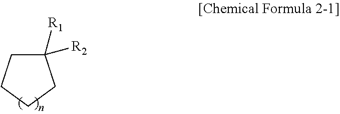

In Chemical Formula 2-1,
R₁ and R₂, are each independently, a hydrogen atom or an alkyl group having 1 to 12 carbon atoms, and when both R₁ and R₂ are an alkyl group, the sum of the number of the carbon atoms of R₁ and R₂ is from 2 to 12, and
n represents an integer of 1 to 3.

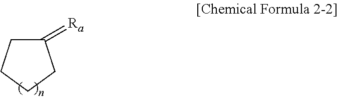

In Chemical Formula 2-2,
Rₐ is an alkenyl group having 1 to 12 carbon atoms, and
n represents an integer of 1 to 3.

More specifically, the cyclic hydrocarbon compound may include one or more types of compounds selected from among 1,1-dimethylcyclohexane, 3-methylbutylcyclopentane, ethylidenecyclopentane, n-octylcyclopentane and n-dodecylcyclopentane.

The cyclic hydrocarbon compound may be included in an amount of 0.01 ppm to 2000 ppm, preferably 0.1 ppm to 2000 ppm and more preferably 0.1 ppm to 100 ppm with respect to the composition, and two or more types of the cyclic hydrocarbon may be mixed and included. When the corresponding content range is satisfied, excellent EBR image and minimized Hump height may be obtained, and film uniformity may be improved. However, in the content of less than 0.01 ppm, film uniformity may not be improved, and in the content of greater than 2000 ppm, the EBR image may deteriorate or the Hump may increase.

In addition, the thinner composition of the present disclosure may further include common additives in addition to the components described above in order to further improve the effects.

In addition, the thinner composition of the present disclosure may not include water. By not including water, dissolution performance for a photoresist may be raised to improve photoresist removal capability.

The thinner composition of the present disclosure may not include an acid compound and an alkaline compound. Since acid and alkaline compounds are not ionized in organic solvents, it is preferred not to include these in order to improve EBR process performance.

The thinner composition of the present disclosure may not include water, an alkaline compound and an acid compound.

### (c) Organic Solvent

In addition, the thinner composition of the present disclosure may further include an organic solvent. When an organic solvent is included, the organic solvent may be included in a residual quantity so that the total weight of the thinner composition becomes 100% including the cyclic ketone-based compound and the cyclic hydrocarbon compound, which are essential components of the thinner composition, or other additives.

The organic solvent of the present disclosure may be used without limit as long as the cyclic ketone-based compound and the cyclic hydrocarbon compound are mixed or dissolved therein.

For example, the organic solvent may include 2-heptanone, ethylene glycol methyl ether, ethyl 3-ethoxypropionate, ethanol, ethyl acetate, isobutyl alcohol, methyl 2-hydroxyisobutyrate, butylene carbonate, n-butyl acetate, propylene carbonate, propanol, propylene glycol methyl ether, propylene glycol monomethyl ether acetate, propylene glycol butyl ether, hexanol and the like, and these may be used either alone or as a mixture of two or more types thereof.

### <Method for Removing Photosensitive Resin and Anti-Reflective Coating>

The present disclosure includes a method for removing a photosensitive resin, a method for removing an anti-reflective coating, and a method for removing a photosensitive resin and an anti-reflective coating.

The method for removing a photosensitive resin and/or an anti-reflective coating of the present disclosure may use the thinner composition of the present disclosure.

For example, the method for removing a photosensitive resin of the present disclosure may include: forming a photosensitive resin on a substrate; and removing the photosensitive resin using the thinner composition. In the method for removing a photosensitive resin of the present disclosure, the removing of the photosensitive resin includes removing a portion of the photosensitive resin formed on the substrate.

In addition, the method for removing an anti-reflective coating of the present disclosure may include: forming an anti-reflective coating on a substrate; and removing the anti-reflective coating using the thinner composition. In the method for removing an anti-reflective coating of the present disclosure, the removing of the anti-reflective coating includes removing a portion of the anti-reflective coating formed on the substrate.

In addition, the method for removing a photosensitive resin and an anti-reflective coating of the present disclosure may include: forming a photosensitive resin on a substrate; forming an anti-reflective coating on the photosensitive resin; and removing the photosensitive resin and the anti-reflective coating using the thinner composition, or may include: forming an anti-reflective coating on a substrate; forming a photosensitive resin on the anti-reflective coating; and removing the photosensitive resin and the anti-reflective coating using the thinner composition. In the method for removing a photosensitive resin and an anti-reflective coating of the present disclosure, the removing of the photosensitive resin and the anti-reflective coating includes removing a portion of the photosensitive resin and the anti-reflective coating formed on the substrate.

In the method for removing a photosensitive resin and/or an anti-reflective coating, the forming of a photosensitive resin and/or an anti-reflective coating on a substrate may use a known method. In addition, the description on the thinner composition may be applied to the method for removing a photosensitive resin and/or an anti-reflective coating in the same manner.

Hereinafter, the present disclosure will be described in more detail with reference to examples. However, the following examples are intended to more specifically describe the present disclosure, and the scope of the present disclosure is not limited by the following examples.

### Examples 1 to 25 and Comparative Examples 1 to 20: Preparation of Thinner Composition

Thinner compositions of Examples 1 to 25 and Comparative Examples 1 to 20 were prepared by mixing components presented in the following Table 1 according to respective content.

Specifications of the components used in the following Examples and Comparative Examples are as follows.

### (A) Cyclic Ketone-Based Compound

(A-1) Cyclopentanone
(A-2) Cyclohexanone
(A-3) Cycloheptanone
(A-4) 1,3-Cyclopentanedione
(A-5) 3-Hydroxycyclopentanone
(A-6) 3-Oxocyclopentanecarboxylic acid

### (B) Linear Ketone-Based Compound

(B-1) Methyl ethyl ketone
(B-2) Acetylacetone
(B-3) 2-Heptanone

### (C) Cyclic Hydrocarbon Compound

(C-1) 1,1-Dimethylcyclohexane
(C-2) 3-Methylbutylcyclopentane
(C-3) Ethylidenecyclopentane
(C-4) n-Octylcyclopentane
(C-5) n-Dodecylcyclopentane

### (D) Linear Hydrocarbon Compound

(D-1) n-Heptanc
(D-2) Dodecane
(D-3) 2.4-Pentadiene

### (E) Organic Solvent

(E-1) Propylene glycol monomethyl ether acetate
(E-2) Ethyl 3-cthoxypropionate
(E-3) Methyl 2-hydroxyisobutyrate
(E-4) Propylene glycol methyl ether

TABLE 1

| | | | | | | | (B) (% by | | | | |
|---|---|---|---|---|---|---|---|---|---|---|---|
| | (% by weight) | | | | | | weight) | | | (C) (ppm) | |
| | Cyclic | | | | | | Linear | | | Cyclic | |
| | Ketone-Based | | | | | | Ketone-Based | | | Hydrocarbon | |
| | Compound | | | | | | Compound | | | Compound | |
| | A-1 | A-2 | A-3 | A-4 | A-5 | A-6 | B-1 | B-2 | B-3 | C-1 | C-2 |
| Example 1 | 25 | | | | | | | | | 100 | |
| Example 2 | | 25 | | | | | | | | 100 | |
| Example 3 | | | 25 | | | | | | | 100 | |
| Example 4 | | | | 25 | | | | | | 100 | |
| Example 5 | | | | | 25 | | | | | 100 | |
| Example 6 | | | | | | 25 | | | | 100 | |
| Example 7 | 25 | | | | | | | | | 100 | |
| Example 8 | 25 | | | | | | | | | 100 | |
| Example 9 | 25 | | | | | | | | | 100 | |
| Example 10 | 25 | | | | | | | | | | 100 |
| Example 11 | 25 | | | | | | | | | | |
| Example 12 | 25 | | | | | | | | | | |
| Example 13 | 25 | | | | | | | | | | |
| Example 14 | 0.1 | | | | | | | | | 100 | |
| Example 15 | 1 | | | | | | | | | 100 | |
| Example 16 | 50 | | | | | | | | | 100 | |
| Example 17 | 99.9 | | | | | | | | | 1000 | |
| Example 18 | | 99.9 | | | | | | | | 1000 | |
| Example 19 | | | 99.9 | | | | | | | 1000 | |
| Example 20 | 99.9 | | | | | | | | | | 1000 |
| Example 21 | 99.9 | | | | | | | | | | |
| Example 22 | 25 | | | | | | | | | 0.01 | |
| Example 23 | 25 | | | | | | | | | 0.1 | |
| Example 24 | 25 | | | | | | | | | 1000 | |
| Example 25 | 25 | | | | | | | | | 2000 | |
| Comparative | | | | | | | 25 | | | 100 | |
| Example 1 | | | | | | | | | | | |
| Comparative | | | | | | | | 25 | | 100 | |
| Example 2 | | | | | | | | | | | |
| Comparative | | | | | | | | | 25 | 100 | |
| Example 3 | | | | | | | | | | | |
| Comparative | | | | | | | 25 | | | | 100 |
| Example 4 | | | | | | | | | | | |
| Comparative | | | | | | | 25 | | | | |
| Example 5 | | | | | | | | | | | |
| Comparative | | | | | | | 25 | | | | |
| Example 6 | | | | | | | | | | | |
| Comparative | | | | | | | 25 | | | | |
| Example 7 | | | | | | | | | | | |
| Comparative | 25 | | | | | | | | | | |
| Example 8 | | | | | | | | | | | |
| Comparative | 25 | | | | | | | | | | |
| Example 9 | | | | | | | | | | | |
| Comparative | 25 | | | | | | | | | | |
| Example 10 | | | | | | | | | | | |
| Comparative | | 25 | | | | | | | | | |
| Example 11 | | | | | | | | | | | |
| Comparative | | | 25 | | | | | | | | |
| Example 12 | | | | | | | | | | | |
| Comparative | | | | 25 | | | | | | | |
| Example 13 | | | | | | | | | | | |
| Comparative | | | | | 25 | | | | | | |
| Example 14 | | | | | | | | | | | |
| Comparative | | | | | | 25 | | | | | |
| Example 15 | | | | | | | | | | | |
| Comparative | 25 | | | | | | | | | | |
| Example 16 | | | | | | | | | | | |
| Comparative | | | | | | | | | | 100 | |
| Example 17 | | | | | | | | | | | |
| Comparative | 99.9 | | | | | | | | | | |
| Example 18 | | | | | | | | | | | |
| Comparative | | | | | | | 99.9 | | | 1000 | |
| Example 19 | | | | | | | | | | | |
| Comparative | 100 | | | | | | | | | | |
| Example 20 | | | | | | | | | | | |

| | (C) (ppm) | | | (D) (ppm) | | | (E) (% by | | | |
|---|---|---|---|---|---|---|---|---|---|---|
| | Cyclic | | | Linear | | | weight) | | | |
| | Hydrocarbon | | | Hydrocarbon | | | Organic | | | |
| | Compound | | | Compound | | | solvent | | | |
| | C-3 | C-4 | C-5 | D-1 | D-2 | D-3 | E-1 | E-2 | E-3 | E-4 |
| Example 1 | | | | | | | 75 | | | |
| Example 2 | | | | | | | 75 | | | |
| Example 3 | | | | | | | 75 | | | |
| Example 4 | | | | | | | 75 | | | |
| Example 5 | | | | | | | 75 | | | |
| Example 6 | | | | | | | 75 | | | |
| Example 7 | | | | | | | | 75 | | |
| Example 8 | | | | | | | | | 75 | |
| Example 9 | | | | | | | | | | 75 |
| Example 10 | | | | | | | 75 | | | |
| Example 11 | 100 | | | | | | 75 | | | |
| Example 12 | | 100 | | | | | 75 | | | |
| Example 13 | | | 100 | | | | 75 | | | |
| Example 14 | | | | | | | 99.9 | | | |
| Example 15 | | | | | | | 99 | | | |
| Example 16 | | | | | | | 50 | | | |
| Example 17 | | | | | | | | | | |
| Example 18 | | | | | | | | | | |
| Example 19 | | | | | | | | | | |
| Example 20 | | | | | | | | | | |
| Example 21 | 1000 | | | | | | | | | |
| Example 22 | | | | | | | 75 | | | |
| Example 23 | | | | | | | 75 | | | |
| Example 24 | | | | | | | 74.9 | | | |
| Example 25 | | | | | | | 74.8 | | | |
| Comparative | | | | | | | 75 | | | |
| Example 1 | | | | | | | | | | |
| Comparative | | | | | | | 75 | | | |
| Example 2 | | | | | | | | | | |
| Comparative | | | | | | | 75 | | | |
| Example 3 | | | | | | | | | | |
| Comparative | | | | | | | 75 | | | |
| Example 4 | | | | | | | | | | |
| Comparative | 100 | | | | | | 75 | | | |
| Example 5 | | | | | | | | | | |
| Comparative | | 100 | | | | | 75 | | | |
| Example 6 | | | | | | | | | | |
| Comparative | | | 100 | | | | 75 | | | |
| Example 7 | | | | | | | | | | |
| Comparative | | | | 100 | | | 75 | | | |
| Example 8 | | | | | | | | | | |
| Comparative | | | | | 100 | | 75 | | | |
| Example 9 | | | | | | | | | | |
| Comparative | | | | | | 100 | 75 | | | |
| Example 10 | | | | | | | | | | |
| Comparative | | | | 100 | | | 75 | | | |
| Example 11 | | | | | | | | | | |
| Comparative | | | | 100 | | | 75 | | | |
| Example 12 | | | | | | | | | | |
| Comparative | | | | 100 | | | 75 | | | |
| Example 13 | | | | | | | | | | |
| Comparative | | | | 100 | | | 75 | | | |
| Example 14 | | | | | | | | | | |
| Comparative | | | | 100 | | | 75 | | | |
| Example 15 | | | | | | | | | | |
| Comparative | | | | | | | 75 | | | |
| Example 16 | | | | | | | | | | |
| Comparative | | | | | | | 100 | | | |
| Example 17 | | | | | | | | | | |
| Comparative | | | | 1000 | | | | | | |
| Example 18 | | | | | | | | | | |
| Comparative | | | | | | | | | | |
| Example 19 | | | | | | | | | | |
| Comparative | | | | | | | | | | |
| Example 20 | | | | | | | | | | |

### Test Example: Evaluation on Thinner Composition Properties

In order to evaluate properties of the thinner compositions prepared according to Examples and Comparative Examples, two types of photoresists presented in the following Table 2 were used, and evaluations were performed under the condition of Table 3 using a 12 inch Track (ACT-12, Tokyo Electron Ltd. (TEL)).

### (1) RRC (Reducing Resist Coating) Test

RRC performance for two photoresists (PR 1, PR 2) of Table 2 was tested using each of the thinner compositions prepared according to the Examples and the Comparative Examples. As shown in Table 3, 4.0 cc of each of the thinner compositions was applied for 3 seconds on a 12-inch silicon wafer in a stationary state before applying a photoresist, and then the substrate was rotated at 2000 rpm for 5 seconds to distribute the thinner over the entire upper surface of the wafer, and 1.0 cc and 0.8 cc of the two types of photoresists (PR) were respectively applied to perform an RRC process of measuring the application distribution and the consumption of the photoresists depending on the thinner. The results are shown in the following Table 4.

### <RRC Evaluation Criteria>

X: less than 80% of the photosensitive film was applied on the wafer as a result of the RRC
Δ: 80% to 95% of the photosensitive film was applied on the wafer as a result of the RRC
o: 95% or more of the photosensitive film was applied on the wafer as a result of the RRC, but there were spots or unapplied areas
⊚: 95% or more of the photosensitive film was applied on the wafer as a result of the RRC, and there were no spots

### (2) EBR (Edge Bead Removal) Test

A photosensitive resin composition described in Table 2 was coated on a 12 inch silicon wafer substrate so that PR was coated over the entire wafer surface under an evaluation condition of the following Table 3, and using each of the thinner compositions, an EBR test of removing an unnecessary photosensitive film in the edge portion was performed under a condition described in the fifth step of the following Table 3. The EBR test was performed for 2 types of PRs, and the evaluation was performed under a condition in which each of the thinner compositions of the Examples and the Comparative Examples was supplied at a constant pressure from a pressure vessel equipped with a pressure gauge, and each of the thinner compositions sprayed at a constant pressure was sprayed in a total amount of 2.2 cc during the EBR process. The evaluated substrate was magnified 400 times and 1,000 times by an optical microscope to identify straightness, uniformity and tailing phenomenon of the EBR line, and the results are shown in the following Table 4. In addition, for the evaluation sample showing straightness and uniformity of the EBR line, a film thickness of 35 μm inside and 35 μm outside the wafer based on the EBR line of the photosensitive film was measured using a film thickness measuring device (Dektak, Bruker Corporation) to derive the maximum film thickness value, and then an average thickness of the photosensitive film was subtracted to calculate a Hump height. The results are shown in the following Table 4.

### <EBR Evaluation Criteria>

X: there was no uniformity in the EBR line for the photosensitive film and a tailing phenomenon occurred after EBR
Δ: there were no straightness and uniformity in the EBR line for the photosensitive film after EBR
o: there was straightness but no uniformity in the EBR line for the photosensitive film after EBR
⊚: there were constant straightness and uniformity in the EBR line for the photosensitive film after EBR

### <Hump Height Result Criteria>

X: Hump height was 1000 Å or greater
Δ: Hump height was 500 Å or greater and less than 1000 Å
o: Hump Height was 100 Å or greater and less than 500 Å
⊚: Hump Height was 100 Å or less

### (3) Uniformity Test

Using each of the thinner compositions prepared according to the Examples and the Comparative Examples, the film thickness of 61 points on the entire surface of the water when coating the two types of photoresists (PR 1, PR 2) of Table 2 was measured, and a standard deviation was calculated to perform uniformity evaluation. As shown in Table 3, 4.0 cc of each of the thinner compositions was applied for 3 seconds on a 12-inch silicon wafer in a stationary state before applying a photoresist, and then the substrate was rotated at 2000 rpm for 5 seconds to distribute the thinner over the entire upper surface of the wafer, and 1.0 cc of each of the two types of PRs was applied.

### <Uniformity Result Criteria>

X: standard deviation σ value was 100 Å or greater for the PR film thickness of 61 points
Δ: standard deviation σ value was 50 Å or greater and less than 100 Å for the PR film thickness of 61 points
o: standard deviation σ value was 20 Å or greater and less than 50 Å for the PR film thickness of 61 points
⊚: standard deviation σ value was less than 20 Å for the PR film thickness of 61 points

TABLE 2

| Classification | PR Type |
|---|---|
| PR 1 | PR A for EUV |
| PR 2 | PR B for ArF |

TABLE 3

| | | | Rotation | |
|---|---|---|---|---|
| Performance | | Time | Speed | |
| Evaluation Step | | (Second) | (rpm) | Details |
| 1 | Thinner | 3 | 0 | Amount of thinner application |
| | Application | | | 4.0 cc |
| 2 | Thinner | 5 | 2000 | |
| | Coating | | | |
| 3 | PR Spray | 5 | 500 | Amount of PR application |
| | Condition | | | 0.5 cc to 4 cc |
| 4 | PR Coating | 20 | 500 to | Adjust according to film |
| | | | 2000 | thickness depending on |
| | | | | application of each PR type |
| 5 | EBR | 9 | 800 | Thinner Spray Speed 15 |
| | Condition | | | mL/min |
| 6 | Soft Baking | 50~60 | — | Temperature 90° C. to |
| | | | | 130° C. depending on PR |

TABLE 4

| | PR 1 | | | | | PR 2 | | | | |
|---|---|---|---|---|---|---|---|---|---|---|
| | RRC | RRC | | Hump | | RRC | RRC | | Hump | |
| Classification | (1.0 cc) | (0.8 cc) | EBR | Height | Uniformity | (1.0 cc) | (0.8 cc) | EBR | Height | Uniformity |
| Example 1 | ⊚ | ◯ | ⊚ | ⊚ | ⊚ | ⊚ | ◯ | ⊚ | ⊚ | ⊚ |
| Example 2 | ⊚ | ◯ | ⊚ | ⊚ | ⊚ | ⊚ | ◯ | ⊚ | ⊚ | ⊚ |
| Example 3 | ⊚ | ⊚ | ⊚ | ⊚ | ⊚ | ⊚ | ⊚ | ⊚ | ⊚ | ⊚ |
| Example 4 | ⊚ | ⊚ | ⊚ | ⊚ | ⊚ | ⊚ | ⊚ | ⊚ | ⊚ | ⊚ |
| Example 5 | ⊚ | ⊚ | ⊚ | ⊚ | ⊚ | ⊚ | ⊚ | ⊚ | ⊚ | ⊚ |
| Example 6 | ⊚ | ⊚ | ⊚ | ⊚ | ⊚ | ⊚ | ⊚ | ⊚ | ⊚ | ⊚ |
| Example 7 | ⊚ | ⊚ | ⊚ | ⊚ | ⊚ | ⊚ | ⊚ | ⊚ | ⊚ | ⊚ |
| Example 8 | ⊚ | ⊚ | ⊚ | ⊚ | ⊚ | ⊚ | ⊚ | ⊚ | ⊚ | ⊚ |
| Example 9 | ⊚ | ◯ | ⊚ | ⊚ | ⊚ | ⊚ | ◯ | ⊚ | ⊚ | ⊚ |
| Example 10 | ⊚ | ◯ | ⊚ | ⊚ | ⊚ | ⊚ | ◯ | ⊚ | ⊚ | ⊚ |
| Example 11 | ⊚ | ◯ | ⊚ | ⊚ | ⊚ | ⊚ | ◯ | ⊚ | ⊚ | ⊚ |
| Example 12 | ⊚ | ◯ | ⊚ | ⊚ | ◯ | ⊚ | ◯ | ⊚ | ⊚ | ◯ |
| Example 13 | ⊚ | ◯ | ⊚ | ⊚ | Δ | ⊚ | ◯ | ⊚ | ⊚ | Δ |
| Example 14 | ⊚ | ⊚ | Δ | Δ | ⊚ | ⊚ | ⊚ | Δ | Δ | ⊚ |
| Example 15 | ⊚ | ⊚ | ◯ | ◯ | ⊚ | ⊚ | ⊚ | ◯ | ◯ | ⊚ |
| Example 16 | ◯ | Δ | ⊚ | ⊚ | ⊚ | ◯ | Δ | ⊚ | ⊚ | ⊚ |
| Example 17 | Δ | Δ | ◯ | ◯ | ◯ | — | — | ◯ | ◯ | ◯ |
| Example 18 | Δ | Δ | ◯ | ◯ | ◯ | — | — | ◯ | ◯ | ◯ |
| Example 19 | Δ | Δ | ◯ | ◯ | ◯ | — | — | ◯ | ◯ | ◯ |
| Example 20 | Δ | Δ | ◯ | ◯ | ◯ | — | — | ◯ | ◯ | ◯ |
| Example 21 | Δ | Δ | ◯ | ◯ | ◯ | — | — | ◯ | ◯ | ◯ |
| Example 22 | ⊚ | ◯ | ⊚ | ⊚ | Δ | ⊚ | ◯ | ⊚ | ⊚ | Δ |
| Example 23 | ⊚ | ◯ | ⊚ | ⊚ | ⊚ | ⊚ | ◯ | ⊚ | ⊚ | ⊚ |
| Example 24 | ⊚ | ◯ | ⊚ | ⊚ | ◯ | ⊚ | ◯ | ⊚ | ⊚ | ◯ |
| Example 25 | ⊚ | ◯ | ⊚ | ⊚ | Δ | ⊚ | ◯ | ⊚ | ⊚ | Δ |
| Comparative Example 1 | ⊚ | ◯ | X | X | X | ⊚ | ◯ | X | Δ | X |
| Comparative Example 2 | ⊚ | ◯ | X | Δ | X | ⊚ | ◯ | X | X | X |
| Comparative Example 3 | ⊚ | ◯ | Δ | X | X | ⊚ | ◯ | X | X | X |
| Comparative Example 4 | ⊚ | ◯ | X | X | X | ⊚ | ◯ | Δ | X | X |
| Comparative Example 5 | ⊚ | ◯ | X | X | X | ⊚ | ◯ | Δ | X | X |
| Comparative Example 6 | ⊚ | ◯ | X | X | X | ⊚ | ◯ | Δ | X | X |
| Comparative Example 7 | ⊚ | ◯ | X | X | X | ⊚ | ◯ | Δ | X | X |
| Comparative Example 8 | ⊚ | ◯ | ⊚ | ⊚ | X | ⊚ | ◯ | ⊚ | ⊚ | X |
| Comparative Example 9 | ⊚ | ◯ | ⊚ | ⊚ | X | ⊚ | ◯ | ⊚ | ⊚ | X |
| Comparative Example 10 | ⊚ | ◯ | ⊚ | ⊚ | X | ⊚ | ◯ | ⊚ | ⊚ | X |
| Comparative Example 11 | ⊚ | ◯ | ⊚ | ⊚ | X | ⊚ | ◯ | ⊚ | ⊚ | X |
| Comparative Example 12 | ⊚ | ⊚ | ⊚ | ⊚ | X | ⊚ | ⊚ | ⊚ | ⊚ | X |
| Comparative Example 13 | ⊚ | ⊚ | ⊚ | ⊚ | X | ⊚ | ⊚ | ⊚ | ⊚ | X |
| Comparative Example 14 | ⊚ | ⊚ | ⊚ | ⊚ | X | ⊚ | ⊚ | ⊚ | ⊚ | X |
| Comparative Example 15 | ⊚ | ⊚ | ⊚ | ⊚ | X | ⊚ | ⊚ | ⊚ | ⊚ | X |
| Comparative Example 16 | ⊚ | ⊚ | ⊚ | ⊚ | X | ⊚ | ⊚ | ⊚ | ⊚ | X |
| Comparative Example 17 | ⊚ | ◯ | X | X | X | ⊚ | ◯ | X | X | X |
| Comparative Example 18 | — | — | ◯ | ◯ | X | — | — | ◯ | ◯ | X |
| Comparative Example 19 | — | — | X | X | X | — | — | X | X | X |
| Comparative Example 20 | — | — | ◯ | ◯ | X | — | — | ◯ | ◯ | X |

Referring to the above-described test results, it was able to be identified that the photoresist treated with the thinner composition of the Example of the present disclosure exhibited excellent uniformity, RRC and EBR properties, and had a low Hump height. In particular, the thinner composition including the cyclic ketone-based compound in an amount of 1% by weight to 50% by weight with respect to the total weight of the composition exhibited more superior effects.

1. A thinner composition comprising:
a cyclic ketone-based compound; and
a cyclic hydrocarbon compound.

2. The thinner composition of claim 1, wherein the cyclic ketone-based compound is included in an amount of 0.1% by weight to 99.9% by weight, and the cyclic hydrocarbon compound is included in an amount of 0.01 ppm to 2000 ppm, with respect to a total weight of the thinner composition.

3. The thinner composition of claim 1, wherein the cyclic ketone-based compound is included in an amount of 1% by weight to 50% by weight, and the cyclic hydrocarbon compound is included in an amount of 0.1 ppm to 2000 ppm, with respect to a total weight of the thinner composition.

4. The thinner composition of claim 1, wherein the cyclic ketone-based compound includes one or more types of compounds selected from the following Chemical Formulae 1-1 to 1-3: 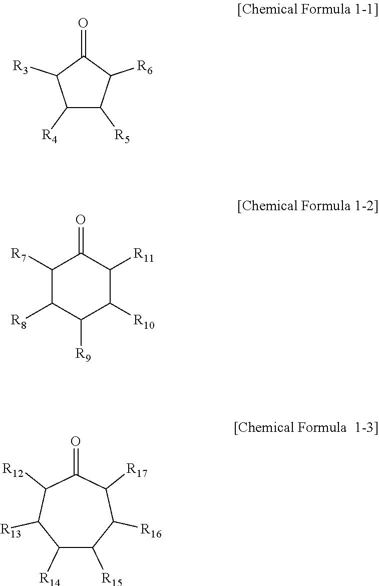
in Chemical Formulae 1-1 to 1-3,
R₃ to R₁₇, each independently, represent a hydrogen atom, an alkyl group having 1 to 5 carbon atoms, a hydroxyl group, an alkyl ether group, a thiol group, an amine group, a carboxyl group, a ketone group, an alkyl ketone group or an alkyl ester group.

5. The thinner composition of claim 1, wherein the cyclic ketone-based compound includes one or more types selected from among cyclopentanone, cyclohexanone, cycloheptanone, 1,3-cyclopentanedione, 3-hydroxycyclopentanone and 3-oxocyclopentanecarboxylic acid.

6. The thinner composition of claim 1, wherein the cyclic hydrocarbon compound includes one or more types of compounds selected from the following Chemical Formula 2-1 and Chemical Formula 2-2: 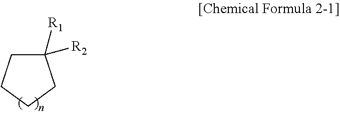
in Chemical Formula 2-1,
R₁ and R₂ are, each independently, a hydrogen atom or an alkyl group having 1 to 12 carbon atoms, and when both R₁ and R₂ are an alkyl group, the sum of the number of the carbon atoms of R₁ and R₂ is from 2 to 12; and
n represents an integer of 1 to 3, 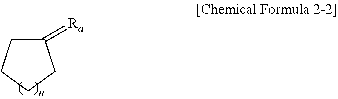
in Chemical Formula 2-2,
Rₐ is an alkenyl group having 1 to 12 carbon atoms; and
n represents an integer of 1 to 3.

7. The thinner composition of claim 1, wherein the cyclic hydrocarbon compound includes one or more types of compounds selected from among 1,1-dimethylcyclohexane, 3-methylbutylcyclopentane, ethylidenecyclopentane, n-octylcyclopentane and n-dodecylcyclopentane.

8. The thinner composition of claim 1, which does not include water, an alkaline compound and an acid compound.

9. The thinner composition of claim 1, which is for removing a photosensitive resin of one or more types of photoresists for ArF, KrF and EUV.

10. A method for removing a photosensitive resin, the method comprising:
forming a photosensitive resin on a substrate; and
removing the photosensitive resin using the thinner composition of claim 1.

11. A method for removing an anti-reflective coating, the method comprising:
forming an anti-reflective coating on a substrate; and
removing the anti-reflective coating using the thinner composition of claim 1.
